(19) United States
(12) Patent Application Publication
(10) Pub. No.: US 2021/0270905 A1
(43) Pub. Date: Sep. 2, 2021

(54) DEVICE AND METHOD FOR MONITORING REMAINING POWER OF BATTERY

(71) Applicant: TEAM YOUNG TECHNOLOGY CO., LTD., Taoyuan City (TW)

(72) Inventors: Tz-Min Lin, Taoyuan City (TW); Dy-Cheng Wang, Taoyuan City (TW)

(73) Assignee: TEAM YOUNG TECHNOLOGY CO., LTD., Taoyuan City (TW)

(21) Appl. No.: 16/926,792

(22) Filed: Jul. 13, 2020

(30) Foreign Application Priority Data
Feb. 27, 2020 (TW) 109106614

(51) Int. Cl. G01R 31/389; H02J 7/00; G01R 31/367; G01R 31/36; G01R 31/3842

(52) U.S. Cl. CPC G01R 31/389; H02J 7/0048; G01R 31/3842; G01R 31/3646; G01R 31/367

(57) ABSTRACT

Device and method for monitoring remaining power of battery, including: measuring a first open circuit voltage value, a first breakover voltage value and a first breakover current value of a battery to obtain an internal resistance value of the battery; at two different times, measuring and obtaining second and third open circuit voltage values which are compared with a preset comparison table or a relationship curve; calculating a difference between second and third remaining power percentage values to obtain a remaining power percentage value difference; measuring a complex breakover current value of the battery in an interval between the two different times, and calculating a Coulomb power by integrating current with time; dividing the Coulomb power by the remaining power percentage value difference to obtain a current maximum power of the battery; obtaining a remaining power of the battery by an open circuit voltage method or a Coulomb integral method.

### CROSS-REFERENCE TO RELATED APPLICATION

This application claims the priority benefit of Taiwan application no. 109106614, filed on Feb. 27, 2020. The entirety of the above-mentioned patent application is hereby incorporated by reference herein and made a part of this specification.

### TECHNICAL FIELD

The invention relates to a device for detecting battery life, and more particularly, to a device and a method for monitoring remaining power of battery.

### BACKGROUND

With the rapid development of electronic technology, terminal devices such as portable electronic products, mobile phones and tablet computers are becoming more important in people's daily lives. Because the terminal device usually needs to maintain operation through charging, displaying of a remaining power of the terminal device is very important for the user.

In addition, the ability to reliably determine the remaining power of a battery of an electric vehicle during transportation for calculating a remaining use time and a driving distance of the vehicle is also highly valued by manufacturers and consumers. In the case of a vehicle powered by fuel, a fuel level can be simply measured. However, in an electric and hybrid vehicle and an electronic device, because the battery is used as a power source, it is difficult to accurately measure the remaining power accumulated in the battery as a life/endurance of the battery will deteriorate due to battery degradation. Thus, showing a power proportion with a battery voltage alone may not give users enough information. At the status of 100% full, because new and old batteries may still have different power levels, problems are likely to occur. In particular, other than electric locomotives, bicycles and electric vehicles, electric devices such as vacuum cleaners and sweeping robots also have the same problems.

Further, there are currently an open circuit voltage method and a Coulomb integral method that can be used to calculate the power of the battery through voltage and current of the battery. Among them, the open voltage method is to measure an open voltage value of the battery, so that an internal power percentage of the battery can be known through a correlation between the open circuit voltage of the battery and a power percentage of the battery. For example, the 4.2V open circuit voltage value of the lithium battery corresponds to 100% power, and the 3.0V open circuit voltage value of the lithium battery corresponds to 0% power. Since this relationship does not change as the battery ages, a remaining power percentage can be effectively obtained by measuring the open circuit voltage. However, the disadvantage of the open circuit voltage method is that it requires an offline open circuit measurement, and the remaining power cannot be effectively estimated without knowing a current maximum power of the battery.

On the other hand, the Coulomb integral method is generally expressed in ampere hours (AH), that is, the current is integrated with time. When the battery is in a charging operation, the Coulomb integral method may be used for accumulation, starting from an initial battery power, so as to obtain a battery power in any calculation period. The battery power may be expressed as:

Q_{T}_{ₙ}=Q_{T}_{₀}∫I(t)dt

wherein t is a current charging time; T₀ is an initial time; Tₙ is a current time; Q_{T}_{₀} is an initial power; Q_{T}_{ₙ} is a current power; I(t) is a charging current. The power is calculated by adding up the power flowed into the battery in ampere hours. The advantage of the Coulomb integral method is that an accurate Coulomb power can be obtained. However, the disadvantage of the Coulomb integral method is that it requires accurate current and time measurement capabilities, and yet there is usually a power error continuously accumulated over time due to time and current measurement errors. The accumulated error can only be eliminated when the battery is fully charged or fully discharged. If “a current maximum power (life)” is unknown, it is impossible to know how much more power can be further charged. Also, the current maximum power of the battery will change with different charging and discharging conditions and battery aging. Therefore, a preset or last maximum power cannot be used for substitution. This means that the battery power cannot be accurately calculated, and thus an available remaining time cannot be effectively estimated.

### SUMMARY

In view of the above deficiencies, the invention aims to provide improved device and method for monitoring remaining power of battery. The invention proposes an accurate measurement technology for the current maximum power of the battery. By using the open circuit voltage method to measure a current power percentage at any two time points to obtain a power percentage difference and using the Coulomb integral method to measure a Coulomb power passed through an interval between the two times, the current maximum power can be calculated. Therefore, by correctly estimating the current maximum power, the remaining power of the battery can be effectively estimated no matter whether the open circuit voltage method or the Coulomb integral method is used in the subsequent process.

To achieve the above purpose, the invention provides a device for monitoring remaining power of battery, which is electrically connected to a battery, and comprises: a voltage measuring unit, electrically connected to the battery, and configured to measure a first open circuit voltage value, a first breakover voltage value, a second open circuit voltage value, a second breakover voltage value, a third open circuit voltage value or a third breakover voltage value of the battery; a current measuring unit, electrically connected to the battery, and configured to measure a first breakover current value, a second breakover current value or a third breakover current value of the battery; and a control unit, electrically connected to the voltage measuring unit and the current measuring unit, wherein the control unit is configured to obtain an internal resistance value of the battery according to the first open circuit voltage value and the first breakover voltage value measured by the voltage measuring unit and the first breakover current value measured by the current measuring unit; at two different times T1 and T2, the control unit obtains the second open circuit voltage value and the third open circuit voltage value according to the second breakover voltage value and the third breakover voltage value measured by the voltage measuring unit, the second breakover current value and the third breakover current value measured by the current measuring unit and the internal resistance value, compares the second open circuit voltage value and the third open circuit voltage value with a preset comparison table or a relationship function curve of a complex open circuit voltage value and a remaining power percentage to obtain a second remaining power percentage value and a third remaining power percentage value corresponding to the second open circuit voltage value and the third open circuit voltage value, and calculates a difference between the second remaining power percentage value and the third remaining power percentage value to obtain a remaining power percentage value difference; a complex breakover current value of the battery is measured in an interval between the two different times T1 and T2, and a Coulomb power passed in the interval between the times T1 and T2 is calculated and obtained by integrating the complex breakover current value with a time of the interval between the times T1 and T2; the Coulomb power is divided by the remaining power percentage value difference to obtain a current maximum power of the battery; and a remaining power of the battery at one time point is obtained according to the current maximum power of the battery by an open circuit voltage method or a Coulomb integral method.

To achieve the above purpose, the invention provides a device for monitoring remaining power of battery, which comprises: a battery; a voltage measuring unit, electrically connected to the battery, and configured to measure a first open circuit voltage value, a first breakover voltage value, a second open circuit voltage value, a second breakover voltage value, a third open circuit voltage value or a third breakover voltage value of the battery; a current measuring unit, electrically connected to the battery, and configured to measure a first breakover current value, a second breakover current value or a third breakover current value of the battery; and a control unit, electrically connected to the voltage measuring unit and the current measuring unit, wherein the control unit is configured to obtain an internal resistance value of the battery according to the first open circuit voltage value and the first breakover voltage value measured by the voltage measuring unit and the first breakover current value measured by the current measuring unit; at two different times T1 and T2, the control unit obtains the second open circuit voltage value and the third open circuit voltage value according to the second breakover voltage value and the third breakover voltage value measured by the voltage measuring unit, the second breakover current value and the third breakover current value measured by the current measuring unit and the internal resistance value, compares the second open circuit voltage value and the third open circuit voltage value with a preset comparison table or a relationship curve of a complex open circuit voltage value and a remaining power percentage to obtain a second remaining power percentage value and a third remaining power percentage value corresponding to the second open circuit voltage value and the third open circuit voltage value, and calculates a difference between the second remaining power percentage value and the third remaining power percentage value to obtain a remaining power percentage value difference; a complex breakover current value of the battery is measured in an interval between the two different times T1 and T2, and a Coulomb power passed in the interval between the times T1 and T2 is calculated and obtained by integrating the complex breakover current value with a time of the interval between the times T1 and T2; the Coulomb power is divided by the remaining power percentage value difference to obtain a current maximum power of the battery; and a remaining power of the battery at one time point is obtained according to the current maximum power of the battery by an open circuit voltage method or a Coulomb integral method.

Further, to achieve the above purpose, in the device for monitoring remaining power of battery, the remaining power is obtained by simultaneously obtaining a first remaining power of the battery by the open circuit voltage method and a second remaining power of the battery by the Coulomb integral method according to the current maximum power of the battery and comparing and processing the first remaining power and the second remaining power, and the remaining power is outputted.

Further, to achieve the above purpose, the device for monitoring remaining power of battery further comprises: a display unit coupled to the control unit, wherein the display unit is configured to display information of the remaining power of the battery according to the remaining power.

Further, to achieve the above purpose, in the device for monitoring remaining power of battery, the control unit is a microcontroller unit (MCU), a personal computer (PC), a programmable logic controller (PLC) or a field-programmable gate array (FPGA).

To achieve the above purpose, the invention provides a method for monitoring remaining power of battery, which comprises: measuring a first open circuit voltage value, a first breakover voltage value and a first breakover current value of a battery; obtaining an internal resistance value of the battery according to the first open circuit voltage value, the first breakover voltage and the first breakover current value; measuring a second breakover voltage value and a third breakover voltage value and a second breakover current value and a third breakover current value of the battery respectively at two different times T1 and T2; obtaining a second open circuit voltage value and a third open circuit voltage value according to the internal resistance value, the second breakover voltage value, the third breakover voltage value, the second breakover current value and the third breakover current value; comparing the second open circuit voltage value and the third open circuit voltage value with a preset comparison table or a relationship function curve of a complex open circuit voltage value and a remaining power percentage to obtain a second remaining power percentage value and a third remaining power percentage value corresponding to the second open circuit voltage value and the third open circuit voltage value; measuring a complex breakover current value of the battery in an interval between the two different times T1 and T2, and calculating and obtaining a Coulomb power passed in the interval between the times T1 and T2 by integrating the complex breakover current value with a time of the interval between the times T1 and T2; obtaining a current maximum power of the battery according to the second remaining power percentage value, the third remaining power percentage value and the Coulomb power; and obtaining a remaining power of the battery at one time point according to the current maximum power of the battery by an open circuit voltage method or a Coulomb integral method.

Further, to achieve the above purpose, in the method for monitoring remaining power of battery, the step of measuring the first open circuit voltage value V_{OC1}, the first breakover voltage value V_{BC1} and the first breakover current value I₁ of the battery to obtain the internal resistance value R of the battery comprises: calculating the internal resistance value R by satisfying a formula (1): R=(V_{BC1}−V_{OC1})/I₁, wherein V_{OC1} is the first open circuit voltage value, V_{BC1} is the first breakover voltage value, and I₁ is the first breakover current value.

Further, to achieve the above purpose, in the method for monitoring remaining power of battery, the step of obtaining the second open circuit voltage value and the third open circuit voltage value according to the internal resistance value, the second breakover voltage value, the third breakover voltage value, the second breakover current value and the third breakover current value comprises: calculating the second open circuit voltage value V_{OC2} by satisfying a formula (2): V_{OC2}=V_{BC2}−I₂×R, and calculating the third open circuit voltage value V_{OC3} by satisfying a formula (3): V_{OC3}=V_{BC3}−I₃×R, wherein V_{BC2} is the second breakover voltage value, I₂ is the second breakover current value, V_{BC3} is the third breakover voltage value, I₃ is the third breakover current value, and R is the internal resistance value.

Further, to achieve the above purpose, in the method for monitoring remaining power of battery, the step of obtaining the current maximum power of the battery according to the second remaining power percentage value, the third remaining power percentage value and the Coulomb power comprises: obtaining the current maximum power Q_{MAX} of the battery by satisfying a formula (4): Q_{MAX}=Q_{T1T2}/(Q_{P3}−Q_{P2}), wherein Q_{P2} is the second remaining power percentage value of the battery at the time T1, Q_{P3} is the third remaining power percentage value of the battery at the time T2, and Q_{T1T2} is the Coulomb power passed in the interval between the times T1 and T2. A negative value of Q_{T1T2} means that the power is reduced and the current flows out from the battery.

Further, to achieve the above purpose, in the method for monitoring remaining power of battery, the remaining power is obtained by simultaneously obtaining a first remaining power of the battery by the open circuit voltage method and a second remaining power of the battery by the Coulomb integral method according to the current maximum power of the battery and comparing and processing the first remaining power and the second remaining power, and the remaining power is outputted, so as to improve the accuracy of monitoring the remaining power.

With the device for monitoring remaining power of battery provided by the invention, users can use relatively simple hardware components, comprising but not limited to the voltage measuring unit, the current measuring unit, and the control unit.

To make the aforementioned and other purposes, features and advantages of the invention more comprehensible, various embodiments accompanied with drawings are described in detail as follows. However, it should be understood by those skilled in the art that, the detailed description and the specific embodiments provided for implementing the invention are simply used to describe the invention rather than limit the scope defined by claims of the invention.

### BRIEF DESCRIPTION OF THE DRAWINGS

FIG. 1 is a block diagram showing a main structure of a device for monitoring remaining power of battery according to a first embodiment of the invention.

FIG. 2 is a block diagram showing a main structure of a device for monitoring remaining power of battery according to a second embodiment of the invention.

FIG. 3 shows a schematic diagram of an equivalent circuit according to the first embodiment and the second embodiment of the invention.

FIG. 4 shows a flowchart of steps in the method for monitoring remaining power of battery according to the invention.

### DETAILED DESCRIPTION

Components and achievable effects disclosed by the invention will be described in the corresponding preferred embodiments below with reference to the drawings. Nonetheless, components, size and appearance of the menu setting device in the drawings are merely used to describe technical features of the invention rather than limit the invention.

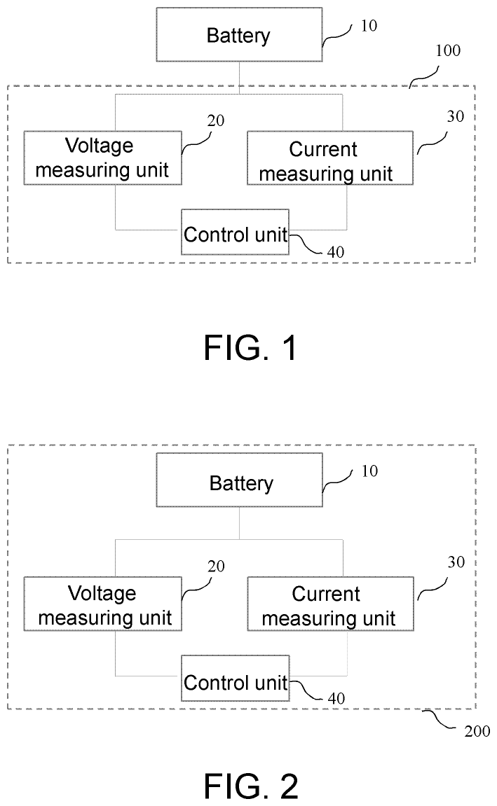

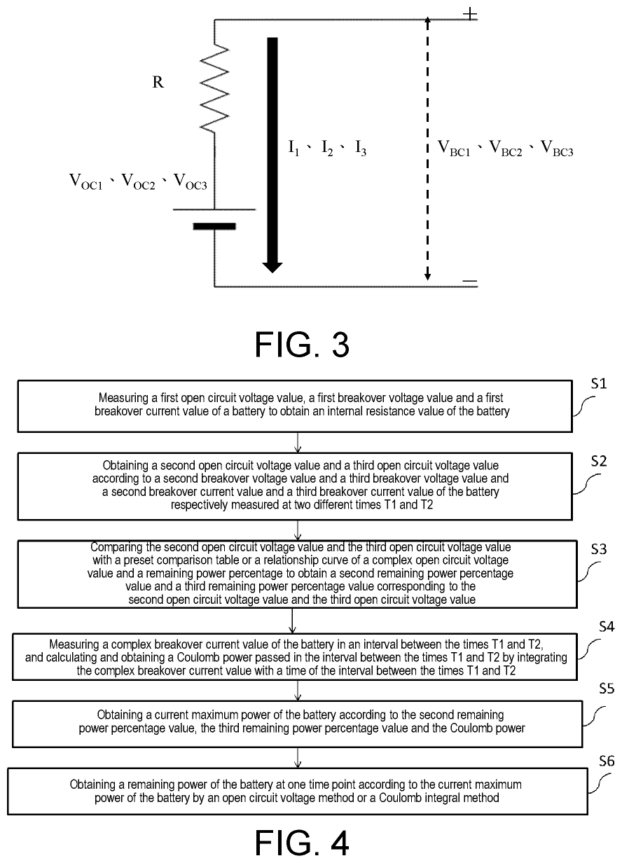

Referring to the first embodiment shown by FIG. 1 and FIG. 3, a device 100 for monitoring remaining power of battery is connected to a battery 10, and comprises a voltage measuring unit 20 electrically connected to the battery 10, a current measuring unit 30 (e.g., an ammeter) electrically connected to the battery 10, and a control unit 40 electrically connected to the voltage measuring unit 20 and the current measuring unit 30. In this embodiment, a current flowed through an internal resistance of the battery 10 will cause a voltage drop, and a measured terminal voltage of the battery 10 comprises such a voltage drop. By measuring a voltage difference between a first breakover voltage value V_{BC1} before the battery 10 is offline and a first open circuit voltage value V_{OC1} after the battery 10 is offline through the voltage measuring unit 20 together with a first breakover current value I₁ measured by the current measuring unit 30, an internal resistance value R of the battery 10 can be obtained, specifically, by satisfying a formula (1): R=(V_{BC1}−V_{OC1})/I₁. Among them, V_{OC1} can be obtained through an offline measurement; V_{BC1} can be obtained through a breakover measurement; and I₁ can be obtained through an external ammeter measurement. Therefore, the internal resistance value R of the battery 10 can be obtained.

Continuing to refer to the first embodiment shown by FIG. 1 and FIG. 3 together, in this embodiment, at two different times T1 and T2, according to a second breakover voltage value V_{BC2} measured at the time T1 and a third breakover voltage value V_{BC3} measured at the time T2 by the voltage measuring unit 20 through the breakover measurement, a second breakover current value I₂ measured at the time T1 and a third breakover current value I₃ measured at the time T2 by the current measuring unit 30 and the calculated internal resistance value R described above, a second open circuit voltage value V_{OC2} and a third open circuit voltage value V_{OC3} can be obtained by, specifically, calculating the second open circuit voltage value V_{OC2} by satisfying a formula (2): V_{OC2}=V_{BC2}−I₂×R, and calculating the third open circuit voltage value V_{OC3} by satisfying a formula (3): V_{OC3}=V_{BC3}−I₃×R, wherein V_{BC2} is the second breakover voltage value, I₂ is the second breakover current value, V_{BC3} is the third breakover voltage value, I₃ is the third breakover current value, and R is the internal resistance value.

Continuing to refer to the first embodiment shown by FIG. 1 and FIG. 3 together, in this embodiment, an internal power percentage of the battery 10 can be obtained by obtaining the open circuit voltage value of the battery 10, and checking a corresponding relationship between the open circuit voltage value of the battery 10 and a power percentage. For example, the 4.2V voltage of the lithium battery corresponds to 100% power, and the 3.0V voltage of the lithium battery corresponds to 0% power. The relationship between the open circuit voltage value and a battery power percentage may be pre-established in form of a comparison table, a look-up table or a relationship function curve (the battery power percentage=f (the open circuit voltage value)). In the invention, the second open circuit voltage V_{OC2} and the third open circuit voltage value V_{OC3} are measured and obtained according to the formula (2) and the formula (3). V_{OC2} and V_{OC3} are substituted into a preset relationship function curve of a complex open circuit voltage value and a remaining power percentage. For example, a second remaining power percentage value Q_{P2} of the battery 10=f (V_{OC2}) at the time T1, and a third remaining power percentage value of the battery Q_{P3} of the battery 10=f (V_{OC3}) at the time T2. Alternatively, the second open circuit voltage value V_{OC2} at the time T1 and the third open circuit voltage value V_{OC3} at the time T2 of the battery 10 are compared with a preset comparison table of the complex open circuit voltage value and the remaining power percentage. Accordingly, when the second open circuit voltage value V_{OC2} at the time T1 and the third open circuit voltage value V_{OC3} at the time T2 are within one specific open circuit voltage range among multiple open circuit voltage ranges (not shown), the second remaining power percentage value Q_{P2} of the battery 10 at the time T1 and the third remaining power percentage value Q_{P3} of the battery 10 at the time T2 are output respectively according to preset remaining power percentage values corresponding the specific open circuit voltage value range. Here, the second remaining power percentage value Q_{P2} refers to the percentage of a remaining power Q₂ of the battery 10 to a current maximum power Q_{MAX} of the battery 10, and the third remaining power percentage value Q_{P3} refers to the percentage of a remaining power Q₃ of the battery 10 to the current maximum power Q_{MAX} of the battery 10.

Continuing to refer to the first embodiment shown by FIG. 1 and FIG. 3 together, in this embodiment, a complex breakover current value I(t) of the battery 10 in an interval between the two different times T1 and T2 is measured by the current measuring unit 30 based on the relationship between current and power:

Q_{T1T2}=∫_{T1}^{T2}I(t)dt

wherein t is a current charging time; t is the interval between the times T1 and T2; a Coulomb power Q_{T1T2} passed in the interval between the times T1 and T2 is calculated and obtained by integrating the complex breakover current value I(t) with the time t of the interval between the two different times T1 and T2. A negative value of Q_{T1T2} means that the power is reduced and the current flows out from the battery 10.

Continuing to refer to the first embodiment shown by FIG. 1 and FIG. 3 together, in this embodiment, the invention proposes an accurate measurement technology for the current maximum power of the battery 10 which is capable of effectively estimating the current maximum power of the battery 10. Therefore, no matter whether the open circuit voltage method or the Coulomb integral method is used in the subsequent process, the remaining power of the battery 10 may be effectively estimated by satisfying a formula (4): Q_{MAX}=Q_{T1T2}/(Q_{P3}−Q_{P2}). Accordingly, the current maximum power Q_{MAX} of the battery 10 can be calculated, wherein Q_{P2} is the second remaining power percentage value of the battery 10 at the time T1, Qₚ₃ is the third remaining power percentage value of the battery 10 at the time T2, and Q_{T1T2} is the Coulomb power passed in the interval between the times T1 and T2. A negative value of Q_{T1T2} means that the power is reduced and the current flows out from the battery 10. Then, a remaining power of the battery 10 at one time point can be obtained according to the current maximum power Q_{MAX} of the battery 10 by the open circuit voltage method or the Coulomb integral method.

Continuing to refer to the first embodiment shown by FIG. 1 and FIG. 3 together, in this embodiment, the control unit 40 of the device 100 for monitoring remaining power of battery of the invention obtains the remaining power of the battery 10. The remaining power is obtained by simultaneously obtaining a first remaining power of the battery 10 by the open circuit voltage method and a second remaining power of the battery 10 by the Coulomb integral method according to the current maximum power of the battery 10 and comparing and processing the first remaining power and the second remaining power, and the remaining power is outputted, so as to improve the accuracy of monitoring the remaining power of the battery 10.

Continuing to refer to the first embodiment shown by FIG. 1, in this embodiment, the device 100 for monitoring remaining power of battery of the invention further comprises a display unit (not shown) coupled to the control unit 40. The display unit (not shown) is configured to display information of the remaining power of the battery 10.

According to the device 100 for monitoring remaining power of battery of the invention, the control unit 40 in the first embodiment is a microcontroller unit (MCU), a personal computer (PC), a programmable logic controller (PLC) or a field-programmable gate array (FPGA).

Referring to the second embodiment shown by FIG. 2 and FIG. 3, as similar to the device 100 for monitoring remaining power of battery in the first embodiment of FIG. 1, a device 200 for monitoring remaining power of battery comprises a battery 10, the voltage measuring unit 20 electrically connected to the battery 10, a current measuring unit 30 (e.g., an ammeter) electrically connected to the battery 10, and a control unit 40 electrically connected to the voltage measuring unit 20 and the current measuring unit 30. In this embodiment, a current flowed through an internal resistance of the battery 10 will cause a voltage drop, and a measured terminal voltage of the battery 10 comprises such a voltage drop. By measuring a voltage difference between a first breakover voltage value V_{BC1} before the battery 10 is offline and a first open circuit voltage value V_{OC1} after the battery 10 is offline through the voltage measuring unit 20 together with a first breakover current value I₁ measured by the current measuring unit 30, an internal resistance value R of the battery 10 can be obtained, specifically, by satisfying a formula (1): R=(V_{BC1}−V_{OC1})/I₁. Among them, V_{OC1} can be obtained through an offline measurement; V_{BC1} can be obtained through a breakover measurement; and I₁ can be obtained through an external ammeter measurement. Therefore, the internal resistance value R of the battery 10 can be obtained.

Continuing to refer to the second embodiment shown by FIG. 2 and FIG. 3 together, in this embodiment, at two different times T1 and T2, according to a second breakover voltage value V_{BC2} measured at the time T1 and a third breakover voltage value V_{BC3} measured at the time T2 by the voltage measuring unit 20 through the breakover measurement, a second breakover current value I₂ measured at the time T1 and a third breakover current value I₃ measured at the time T2 by the current measuring unit 30 and the calculated internal resistance value R described above, a second open circuit voltage value V_{OC2} and a third open circuit voltage value V_{OC3} can be obtained by, specifically, calculating the second open circuit voltage value V_{OC2} by satisfying a formula (2): V_{OC2}=V_{BC2}−I₂×R, and calculating the third open circuit voltage value OC3 by satisfying a formula (3): V_{OC3}=V_{BC3}−I₃×R, wherein V_{BC2} is the second breakover voltage value, I₂ is the second breakover current value, V_{BC3} is the third breakover voltage value, I₃ is the third breakover current value, and R is the internal resistance value.

Continuing to refer to the second embodiment shown by FIG. 2 and FIG. 3 together, in this embodiment, an internal power percentage of the battery 10 can be obtained by obtaining the open circuit voltage value of the battery 10, and checking a corresponding relationship between the open circuit voltage value of the battery 10 and a power percentage. For example, the 4.2V open circuit voltage value of the lithium battery corresponds to 100% power, and the 3.0V open circuit voltage value of the lithium battery corresponds to 0% power. The relationship between the open circuit voltage value and a battery power percentage can be pre-established in form of a comparison table, a look-up table or a relationship function curve (the battery power percentage=f (the open circuit voltage value)). In the invention, the second open circuit voltage V_{OC2} and the third open circuit voltage value V_{OC3} are measured and obtained according to the formula (2) and the formula (3). V_{OC2} and V_{OC3} are substituted into a preset relationship function curve of a complex open circuit voltage value and a remaining power percentage. For example, a second remaining power percentage value Q_{P2} of the battery 10=f (V_{OC2}) at the time T1, and a third remaining power percentage value of the battery Q_{P3} of the battery 10=f (V_{OC3}) at the time T2. Alternatively, the second open circuit voltage value V_{OC2} at the time T1 and the third open circuit voltage value V_{OC3} at the time T2 of the battery 10 are compared with a preset comparison table of the complex open circuit voltage value and the remaining power percentage. Accordingly, when the second open circuit voltage value V_{OC2} at the time T1 and the third open circuit voltage value V_{OC3} at the time T2 are within one specific open circuit voltage range among multiple open circuit voltage ranges (not shown), the second remaining power percentage value Q_{P2} of the battery 10 at the time T1 and the third remaining power percentage value Q_{P3} of the battery 10 at the time T2 are output respectively according to preset remaining power percentage values corresponding the specific open circuit voltage value range. Here, the second remaining power percentage value Q_{P2} refers to the percentage of a remaining power Q₂ of the battery 10 to a current maximum power Q_{MAX} of the battery 10, and the third remaining power percentage value Q_{P3} refers to the percentage of a remaining power Q₃ of the battery 10 to the current maximum power Q_{MAX} of the battery 10.

Continuing to refer to the second embodiment shown by FIG. 2 and FIG. 3 together, in this embodiment, a complex breakover current value I(t) of the battery 10 in an interval between the two different times T1 and T2 is measured by the current measuring unit 30 based on the relationship between current and power:

Q_{T1T2}=∫_{T1}^{T2}I(t)dt

wherein t is a current charging time; t is the interval between the times T1 and T2; a Coulomb power Q_{T1T2} passed in the interval between the times T1 and T2 is calculated and obtained by integrating the complex breakover current value I(t) with the time t of the interval between the two different times T1 and T2. A negative value of Q_{T1T2} means that the power is reduced and the current flows out from the battery 10.

Continuing to refer to the second embodiment shown by FIG. 2 and FIG. 3 together, in this embodiment, the invention proposes an accurate measurement technology for the current maximum power of the battery 10 which is capable of effectively estimating the current maximum power of the battery 10. Therefore, no matter whether the open circuit voltage method or the Coulomb integral method is used in the subsequent process, the remaining power of the battery 10 can be effectively estimated by satisfying a formula (4): Q_{MAX}=Q_{T1T2}/(Q_{P3}−Q_{P2}). Accordingly, the current maximum power Q_{MAX} of the battery 10 can be calculated, wherein Q_{P2} is the second remaining power percentage value of the battery 10 at the time T1, Q_{P3} is the third remaining power percentage value of the battery 10 at the time T2, and Q_{T1T2} is the Coulomb power passed in the interval between the times T1 and T2. A negative value of Q_{T1T2} means that the power is reduced and the current flows out from the battery 10. Then, a remaining power of the battery 10 at one time point can be obtained according to the current maximum power Q_{MAX} of the battery 10 by the open circuit voltage method or the Coulomb integral method.

Continuing to refer to the second embodiment shown by FIG. 2 and FIG. 3 together, in this embodiment, the control unit 40 of the device 200 for monitoring remaining power of battery of the invention obtains the remaining power of the battery 10. The remaining power is obtained by simultaneously obtaining a first remaining power of the battery 10 by the open circuit voltage method and a second remaining power of the battery 10 by the Coulomb integral method according to the current maximum power of the battery 10 and comparing and processing the first remaining power and the second remaining power, and the remaining power is outputted, so as to improve the accuracy of monitoring the remaining power of the battery 10.

Continuing to refer to the second embodiment shown by FIG. 2, in this embodiment, the device 200 for monitoring remaining power of battery of the invention further comprises a display unit (not shown) coupled to the control unit 40. The display unit (not shown) is configured to display information of the remaining power of the battery 10.

Continuing to refer to the second embodiment shown by FIG. 2, in this embodiment, according to the device 200 for monitoring remaining power of battery of the invention, the control unit 40 is a microcontroller unit (MCU), a personal computer (PC), a programmable logic controller (PLC) or a field-programmable gate array (FPGA).

Referring to the descriptions of FIG. 1, FIG. 2, FIG. 3 and FIG. 4 together, FIG. 4 shows a flowchart of steps in the method for monitoring remaining power of battery according to the invention, which can be used by the device 100 for monitoring remaining power of battery of FIG. 1 and the device 200 for monitoring remaining power of battery of FIG. 2. However, the method for monitoring remaining power of battery of the invention is not limited to thereto. In this embodiment, the method for monitoring remaining power of battery of the invention comprises the following steps. Step S1: a first open circuit voltage value V_{OC1}, a first breakover voltage value V_{BC1} and a first breakover current value I₁ of the battery 10 are measured; an internal resistance value R of the battery is obtained according to the first open circuit voltage value V_{OC1}, the first breakover voltage V_{BC1} and the first breakover current value I₁. Step S2: a second breakover voltage value V_{BC2} and a third breakover voltage value V_{BC3} and a second breakover current value I₂ and a third breakover current value I₃ of the battery 10 are measured respectively at two different times T1 and T2; a second open circuit voltage value V_{OC2} and a third open circuit voltage value V_{OC3} are obtained according to the internal resistance value R, the second breakover voltage value V_{BC2}, the third breakover voltage value V_{BC3}, the second breakover current value I₂ and the third breakover current value I₃. Step S3: the second open circuit voltage value V_{OC2} and the third open circuit voltage value V_{OC3} are compared with a preset comparison table or a relationship function curve of a complex open circuit voltage value and a remaining power percentage. That is, there is a corresponding relationship between the open circuit voltage value of the battery 10 and a power percentage. For example, the 4.2V open circuit voltage value of the lithium battery corresponds to 100% power, and the 3.0V open circuit voltage value of the lithium battery corresponds to 0% power. Accordingly, a second remaining power percentage value and a third remaining power percentage value corresponding to the second open circuit voltage value V_{OC2} and the third open circuit voltage value V_{OC3} are obtained. Step S4: a complex breakover current value of the battery 10 is measured in an interval between the two different times T1 and T2, and a Coulomb power passed in the interval between the times T1 and T2 is calculated and obtained by integrating the complex breakover current value with a time of the interval between the times T1 and T2. Step S5: a current maximum power of the battery 10 is obtained according to the second remaining power percentage value, the third remaining power percentage value and the Coulomb power. Step S6: a remaining power of the battery 10 at one time point is obtained according to the current maximum power of the battery 10 by an open circuit voltage method or a Coulomb integral method.

In step S1, the step of measuring the first open circuit voltage value V_{OC1}, the first breakover voltage value V_{BC1} and the first breakover current value I₁ of the battery to obtain the internal resistance value R of the battery comprises: calculating the internal resistance value R by satisfying a formula (1): R=(V_{BC1}−V_{OC1})/I₁, wherein V_{OC1} is the first open circuit voltage value, V_{BC1} is the first breakover voltage value, and I₁ is the first breakover current value.

In step S2, the step of obtaining the second open circuit voltage value V_{OC2} and the third open circuit voltage value V_{OC3} according to the internal resistance value R, the second breakover voltage value V_{BC2}, the third breakover voltage value V_{BC3}, the second breakover current value I₂ and the third breakover current value I₃ comprises: calculating the second open circuit voltage value V_{OC2} by satisfying a formula (2): V_{OC2}=V_{BC2}−I₂×R, and calculating the third open circuit voltage value V_{OC3} by satisfying a formula (3): V_{OC3}=V_{BC3}−I₃×R, wherein V_{BC2} is the second breakover voltage value, I₂ is the second breakover current value, V_{BC3} is the third breakover voltage value, I₃ is the third breakover current value, and R is the internal resistance value.

In step S5, the step of obtaining the current maximum power Q_{MAX} of the battery 10 according to the second remaining power percentage value Q_{P2}, the third remaining power percentage value Q_{P3} and the Coulomb power Q_{T1T2} comprises: obtaining the current maximum power Q_{MAX} of the battery 10 by satisfying a formula (4): Q_{MAX}=Q_{T1T2}/(Q_{P3}−Q_{P2}), wherein Q_{P2} is the second remaining power percentage value of the battery 10 at the time T1, Q_{P3} is the third remaining power percentage value of the battery 10 at the time T2, and Q_{T1T2} is the Coulomb power passed in the interval between the times T1 and T2. A negative value of Q_{T1T2} means that the power is reduced and the current flows out from the battery 10.

In step S6, since the power obtained by the open circuit voltage method is actually the power charged into or discharged from the battery 10 and the Coulomb integral method is the power charged into or discharged from the battery by an external power source, the remaining power is obtained by simultaneously obtaining a first remaining power of the battery 10 by the open circuit voltage method and a second remaining power of the battery 10 by the Coulomb integral method according to the current maximum power of the battery 10 and comparing and processing the first remaining power and the second remaining power, and the remaining power is outputted. As a result, the accuracy of monitoring the remaining power of the battery 10 can be improved.

In summary, the device and the method for monitoring remaining power of battery disclosed by the invention are to provide improved device and method for monitoring the remaining power of the battery 10. The invention proposes an accurate measurement technology for the current maximum power of the battery 10 which is capable of effectively estimating the current maximum power of the battery 10. Therefore, with the current maximum power of the battery 10 estimated by the device and the method for monitoring remaining power of battery of the invention, the remaining power of the battery can be correctly estimated no matter whether the open circuit voltage method or the Coulomb integral method is used in the subsequent process.

Finally, it is to be understood that the constituent elements disclosed in foregoing embodiments of the invention are merely examples rather than limitations to the scope of the invention. Other replacements or modifications of the equivalent element should be covered by the scope defined by claims of the invention.

1. A device for monitoring remaining power of battery, electrically connected to a battery, and comprising:
a voltage measuring unit, electrically connected to the battery, and configured to measure a first open circuit voltage value, a first breakover voltage value, a second open circuit voltage value, a second breakover voltage value, a third open circuit voltage value or a third breakover voltage value of the battery;
a current measuring unit, electrically connected to the battery, and configured to measure a first breakover current value, a second breakover current value or a third breakover current value of the battery; and
a control unit, electrically connected to the voltage measuring unit and the current measuring unit,
wherein the control unit is configured to obtain an internal resistance value of the battery according to the first open circuit voltage value and the first breakover voltage value measured by the voltage measuring unit and the first breakover current value measured by the current measuring unit; at two different times T1 and T2, the control unit obtains the second open circuit voltage value and the third open circuit voltage value according to the second breakover voltage value and the third breakover voltage value measured by the voltage measuring unit, the second breakover current value and the third breakover current value measured by the current measuring unit and the internal resistance value, compares the second open circuit voltage value and the third open circuit voltage value with a preset comparison table or a relationship function curve of a complex open circuit voltage value and a remaining power percentage to obtain a second remaining power percentage value and a third remaining power percentage value corresponding to the second open circuit voltage value and the third open circuit voltage value, and calculates a difference between the second remaining power percentage value and the third remaining power percentage value to obtain a remaining power percentage value difference; a complex breakover current value of the battery is measured in an interval between the two different times T1 and T2, and a Coulomb power passed in the interval between the two different times T1 and T2 is calculated and obtained by integrating the complex breakover current value with a time of the interval between the times T1 and T2; the Coulomb power is divided by the remaining power percentage value difference to obtain a current maximum power of the battery; and a remaining power of the battery at one time point is obtained according to the current maximum power of the battery by an open circuit voltage method or a Coulomb integral method.

2. The device for monitoring remaining power of battery according to claim 1, wherein the remaining power is obtained by simultaneously obtaining a first remaining power of the battery by the open circuit voltage method and a second remaining power of the battery by the Coulomb integral method according to the current maximum power of the battery and comparing and processing the first remaining power and the second remaining power, and the remaining power is outputted.

3. The device for monitoring remaining power of battery according to claim 1, further comprising: a display unit coupled to the control unit, wherein the display unit is configured to display information of the remaining power of the battery according to the remaining power.

4. The device for monitoring remaining power of battery according to claim 1, wherein the control unit is a microcontroller unit (MCU), a personal computer (PC), a programmable logic controller (PLC) or a field-programmable gate array (FPGA).

5. A device for monitoring remaining power of battery, comprising:
a battery;
a voltage measuring unit, electrically connected to the battery, and configured to measure a first open circuit voltage value, a first breakover voltage value, a second open circuit voltage value, a second breakover voltage value, a third open circuit voltage value or a third breakover voltage value of the battery;
a current measuring unit, electrically connected to the battery, and configured to measure a first breakover current value, a second breakover current value or a third breakover current value of the battery; and
a control unit, electrically connected to the voltage measuring unit and the current measuring unit,
wherein the control unit is configured to obtain an internal resistance value of the battery according to the first open circuit voltage value and the first breakover voltage value measured by the voltage measuring unit and the first breakover current value measured by the current measuring unit; at two different times T1 and T2, the control unit obtains the second open circuit voltage value and the third open circuit voltage value according to the second breakover voltage value and the third breakover voltage value measured by the voltage measuring unit, the second breakover current value and the third breakover current value measured by the current measuring unit and the internal resistance value, compares the second open circuit voltage value and the third open circuit voltage value with a preset comparison table or a relationship function curve of a complex open circuit voltage value and a remaining power percentage to obtain a second remaining power percentage value and a third remaining power percentage value corresponding to the second open circuit voltage value and the third open circuit voltage value, and calculates a difference between the second remaining power percentage value and the third remaining power percentage value to obtain a remaining power percentage value difference; a complex breakover current value of the battery is measured in an interval between the two different times T1 and T2, and a Coulomb power passed in the interval between the two different times T1 and T2 is calculated and obtained by integrating the complex breakover current value with a time of the interval between the times T1 and T2; the Coulomb power is divided by the remaining power percentage value difference to obtain a current maximum power of the battery; and a remaining power of the battery at one time point is obtained according to the current maximum power of the battery by an open circuit voltage method or a Coulomb integral method.

6. The device for monitoring remaining power of battery according to claim 5, wherein the remaining power is obtained by simultaneously obtaining a first remaining power of the battery by the open circuit voltage method and a second remaining power of the battery by the Coulomb integral method according to the current maximum power of the battery and comparing and processing the first remaining power and the second remaining power, and the remaining power is outputted.

7. The device for monitoring remaining power of battery according to claim 5, further comprising: a display unit coupled to the control unit, wherein the display unit is configured to display information of the remaining power of the battery according to the remaining power.

8. The device for monitoring remaining power of battery according to claim 5, wherein the control unit is a microcontroller unit (MCU), a personal computer (PC), a programmable logic controller (PLC) or a field-programmable gate array (FPGA).

9. A method for monitoring remaining power of battery, comprising:
measuring a first open circuit voltage value, a first breakover voltage value and a first breakover current value of a battery to obtain an internal resistance value of the battery;
measuring a second breakover voltage value and a third breakover voltage value and a second breakover current value and a third breakover current value of the battery respectively at two different times T1 and T2;
obtaining a second open circuit voltage value and a third open circuit voltage value according to the internal resistance value, the second breakover voltage value, the third breakover voltage value, the second breakover current value and the third breakover current value;
comparing the second open circuit voltage value and the third open circuit voltage value with a preset comparison table or a relationship function curve of a complex open circuit voltage value and a remaining power percentage to obtain a second remaining power percentage value and a third remaining power percentage value corresponding to the second open circuit voltage value and the third open circuit voltage value;
measuring a complex breakover current value of the battery in an interval between the two different times T1 and T2, and calculating and obtaining a Coulomb power passed in the interval between the times T1 and T2 by integrating the complex breakover current value with a time of the interval between the times T1 and T2;
obtaining a current maximum power of the battery according to the second remaining power percentage value, the third remaining power percentage value and the Coulomb power; and
obtaining a remaining power of the battery at one time point according to the current maximum power of the battery by an open circuit voltage method or a Coulomb integral method.

10. The method for monitoring remaining power of battery according to claim 9, wherein the step of measuring the first open circuit voltage value, the first breakover voltage value and the first breakover current value of the battery to obtain the internal resistance value of the battery comprises: calculating the internal resistance value R by satisfying a formula (1): R=(V_{BC1}−V_{OC1})/I₁, wherein V_{OC1} is the first open circuit voltage value, V_{BC1} is the first breakover voltage value, and I₁ is the first breakover current value.

11. The method for monitoring remaining power of battery according to claim 9, wherein the step of obtaining the second open circuit voltage value and the third open circuit voltage value according to the internal resistance value, the second breakover voltage value, the third breakover voltage value, the second breakover current value and the third breakover current value comprises: calculating the second open circuit voltage value V_{OC2} by satisfying a formula (2): V_{OC2}=V_{BC2}−I₂×R, and calculating the third open circuit voltage value V_{OC3} by satisfying a formula (3): V_{OC3}=V_{BC3}−I₃×R, wherein V_{BC2} is the second breakover voltage value, I₂ is the second breakover current value, V_{BC3} is the third breakover voltage value, I₃ is the third breakover current value, and R is the internal resistance value.

12. The method for monitoring remaining power of battery according to claim 9, wherein the step of obtaining the current maximum power of the battery according to the second remaining power percentage value, the third remaining power percentage value and the Coulomb power comprises: obtaining the current maximum power Q_{MAX} of the battery by satisfying a formula (4): Q_{MAX}=Q_{T1T2}/(Q_{P3}−Q_{P2}), wherein Q_{P2} is the second remaining power percentage value of the battery at the time T1, Q_{P3} is the third remaining power percentage value of the battery at the time T2, and Q_{T1T2} is the Coulomb power passed in the interval between the times T1 and T2.

13. The method for monitoring remaining power of battery according to claim 9, wherein the remaining power is obtained by simultaneously obtaining a first remaining power of the battery by the open circuit voltage method and a second remaining power of the battery by the Coulomb integral method according to the current maximum power of the battery and comparing and processing the first remaining power and the second remaining power, and the remaining power is outputted.
